(19) United States
(12) Patent Application Publication
(10) Pub. No.: US 2026/0004225 A1
(43) Pub. Date: Jan. 1, 2026

(54) DIGITAL TWIN-BASED AUTOMATED LOGISTICS FACILITY OPERATION SYSTEM AND METHOD

(71) Applicants: Hyundai Motor Company, Seoul (KR); Kia Corporation, Seoul (KR)

(72) Inventors: Jongho Shin, Hwaseong (KR); Sunkyung Choi, Hwaseong (KR); Yoon Jang, Hwaseong (KR); Youngwan Ko, Hwaseong (KR); Yu Sung Jang, Hwaseong (KR); Hyoung Su Pae, Hwaseong (KR)

(21) Appl. No.: 19/240,752

(22) Filed: Jun. 17, 2025

(30) Foreign Application Priority Data
Jun. 28, 2024 (KR) 10-2024-0084923

(51) Int. Cl. G06Q 10/08; G06F 30/20

(52) U.S. Cl. CPC G06Q 10/08; G06F 30/20

(57) ABSTRACT

An automated logistics facility operation system may include an interface configured to support heterogeneous communication protocols with respect to various automated logistics facilities operated in a logistics terminal and collect facility data in real time, a server configured to mirror the facility data of an actual logistics facility and a virtual environment according to the facility data uploaded from the interface, a packaging simulator configured to derive a cargo deployment sequence and disposal location within a designated space, through a loading algorithm utilizing the facility data of the server, and a client device capable of commanding a loading sequence of the cargo matching a packaging simulation result and a loading work within the designated space.

### CROSS-REFERENCE TO RELATED APPLICATION

This application claims under 35 U.S.C. § 119 (a) the benefit of Korean Patent Application No. 10-2024-0084923 filed with the Korean Intellectual Property Office on Jun. 28, 2024, the entire contents of which are incorporated herein by reference.

### BACKGROUND

### (a) Technical Field

The present disclosure relates to an automated logistics facility operation system and method, more particularly, the present disclosure relates to the automated logistics facility operation system and method that utilizes digital twin-based logistics loading simulation.

### (b) Description of the Related Art

Conventional logistics technology is typically divided into three types, i.e., logistics automated facilities, logistics loading algorithms, and logistics line monitoring (e.g., enterprise resource planning, ERP) systems.

Recently, logistics terminals have introduced logistics automated facilities for entering, storing, and releasing cargo, and control facilities for on-site facility operation. Accordingly, logistics terminals are introducing logistics loading algorithms and logistics line monitoring systems in order to achieve efficient operation of between logistics automated facilities.

However, conventionally, individual control facilities and corresponding workers are required for different types of logistics automated facilities, and logistics line monitoring system was limited to monitoring malfunctioning facilities on site and sending an alarm to a relevant worker.

In addition, conventional logistics loading algorithms depend on the experience (skill) of workers for loading cargo inside a cargo vehicle container, an aircraft unit load device (ULD), and/or a ship container. However, according to these cargo loading methods, cargo loading efficiency can vary depending on the experience of the workers. For example, when loading cargo into a limited space inside a cargo container (container/ULD), if the worker's experience is low, the problem of deterioration the loading efficiency and safety (e.g., bias/collapse, or the like) may be caused. When there is deterioration of the loading efficiency or stability, since there may be a cargo damage or relocation must be repeated, there is a disadvantage in that loading working man-hours, time, and cost may increase. In particular, when the size and shape of cargo containers, and the volume and weight of cargos vary depending on cargo vehicles, aircraft, and vessels, the conventional method that relies on the worker's experience may have a disadvantage in that the optimal cargo loading efficiency cannot be ensured.

The above information disclosed in this Background section is only for enhancement of understanding of the background of the disclosure, and therefore it may contain information that does not form the prior art that is already known in this country to a person of ordinary skill in the art.

### SUMMARY

The present disclosure provides a digital automated logistics facility operation system and method, which links a cyber-physical systems (CPS) mode, in which data of the actual logistics terminal and an automation equipment within a virtual environment are synchronized and mirrored in real-time based on a digital twin (DT), and the control function of a simulation mode, in which a virtual condition is modified and predicted, with a switching structure.

According to the present disclosure, a digital automated logistics facility operation system may include: an interface configured to support heterogeneous communication protocols with respect to various automated logistics facilities operated in a logistics terminal and collect facility data in real time; a server configured to mirror the facility data of an actual logistics facility and a virtual environment according to the facility data uploaded from the interface; a packaging simulator configured to derive a cargo deployment sequence and disposal location within a designated space, through a loading algorithm utilizing the facility data of a server; and a client device capable of commanding a loading sequence of the cargo matching a packaging simulation result and a loading work within the designated space.

For example, the interface may be an Internet of Things interface (IoT I/F), and the server may be configured as a digital twin (DT) server. Any server suitable for performing the functions as described herein may be referred to as a DT server.

According to another aspect of the present disclosure, a digital automated logistics facility operation system may include an Internet of Things interface (IoT I/F) configured to support heterogeneous communication protocols with respect to various automated logistics facilities operated in a logistics terminal and collect facility data in real time, a server configured to mirror the facility data of an actual logistics facility and a virtual environment according to the facility data uploaded from the IoT I/F, a packaging simulator configured to derive a cargo deployment sequence and disposal location within a designated space, through a loading algorithm utilizing the facility data of a DT server, and a DT client capable of commanding a loading sequence of the cargo matching a packaging simulation result and a loading work within the designated space.

The logistics facility may include a cargo recognition unit configured to measure a cargo ID, volume, weight of the entered cargo through a measurement device, a robot equipment unit including a loading robot, a forklift robot, a transport robot, and a picking robot, configured to handle the cargo, an automated warehouse configured to store the cargo in a cell space of a multi-layer structure and identify real-time cargo storing information through a sensor and transmit the identified information to the IoT I/F, a loading platform having a forklift pick-up structure and a cargo loading space of a pallet structure, and a cargo container including a container and a unit load device (ULD) capable of loading the cargo of a large amount depending on a transport vehicle.

The IoT I/F may be configured to upload a recognized cargo information including a 3D mesh modeling file of the cargo through 3D vision to a DB table of the DT server and share the recognized cargo information by transmitting the recognized cargo information to the ERP configured to manage entry/release reservation information of the cargo.

The DT server may be configured to link a cyber-physical systems (CPS) mode of the virtual environment mirrored with the logistics terminal and a control function of a simulation mode of predicting operation efficiency according to modifying of facility operation condition of the virtual environment through the packaging simulator to the DT client in the form of a switching structure.

The DT client may be configured to control an operation state of the logistics facility at a place remote from an on-site of the logistics terminal through the simulation mode and the CPS mode of the DT server.

The DT client may be configured to command an entering work, a releasing work and a loading work of the designated cargo by being linked with the DT server.

The DT client may be configured to reproduce a black box image as a simulation based on a cargo log and a time chart of an object by logging a loading work result of the cargo into a DB.

The DT server may include a communication unit configured to relay data transmission/reception between the IoT I/F, the packaging simulator, and the DT client, a virtual object generator configured to generate a virtual object based on regular and irregular cargo information including a 3D mesh modeling file and the facility data of the logistics terminal collected from the IoT I/F, a cyber-physical systems (CPS) configured to implement a mirrored CPS mode by disposing the virtual object within the virtual environment simulating the logistics terminal and processing real-time synchronization on the facility data of an actual environment, a database (DB) configured to manage DB tables respectively corresponding to the facility data, logistics information, and the simulation result, and a controller configured to transfer data enabling driving of an object in the virtual environment simulating the actual logistics facility according to a request of the DT client.

The CPS may be configured to convert the facility data collected in real time at the time of the CPS mode into a motion sequence within the virtual environment and display the converted motion sequence to the user in a virtual environment mirroring animation.

The CPS may be configured to output a meaningful facility operation indicator by analyzing a difference in the simulation result when the cargo of the same condition is operated in the simulation.

The controller may be configured to register the DT client and store the registered DT client in the DB, and grant a control authority for operating the automated logistics facility of the logistics terminal to the DT client connected through user authentication.

The data transferred by the controller may include facility data synchronized with the actual logistics facility in real time according to a CPS mode request of the DT client and two types of task parser signals simulating information transmitted/received between the logistics facility and the IoT I/F according to a simulation mode request.

The controller may be configured to load the cargo information, modeling shape information, and loading space information to the packaging simulator according to the simulation mode request, and the packaging simulator may be configured to derive the cargo deployment sequence and the deployment location through the loading algorithm using the loaded information and transfer the derived information to the controller.

The controller may be configured to transfer an optimal cargo deployment sequence and disposal location derived as a simulator result to the DT client, and the DT client may be configured to transmit a logistics facility control instruction according to the cargo deployment sequence and the deployment location to the IoT I/F through the DT server.

According to the present disclosure, an automated logistics facility operation method of a client device operating based on a server, the method comprising: selecting, by the client device, whether a CPS mode or a simulation mode is to be executed during a normal operation of the server; receiving, by the client device, a digital twin service based on the facility data synchronized with an actual logistics facility in real time, by communicating with an interface and checking facility data, when the CPS mode is selected; requesting, by the client device, an operation of a task parser for generating a work command, when the simulation mode is selected; loading information of the server according to a work command generating processor of the task parser; and calling, by the client device, a packaging simulator according to the loading of the loading information and receiving a loading sequence result value derived through a loading algorithm-based simulation.

According to a further aspect of the present disclosure, an automated logistics facility operation method of a DT client operating based on a digital twin (DT) server may include selecting whether a CPS mode or a simulation mode is to be executed during a normal operation of the DT server, receiving a digital twin service based on the facility data synchronized with an actual logistics facility in real time, by communicating with an IoT I/F and checking an facility data, when the CPS mode is selected, requesting an operation of a task parser for generating a work command, when the simulation mode is selected, loading information of the DT server according to a work command generating processor of the task parser, and calling a packaging simulator according to the loading of the loading information and receiving a loading sequence result value derived through a loading algorithm-based simulation.

The receiving the loading sequence result value may include generating a cargo list to be loaded for each destination according to a reality-based simulation condition through linking with an upper ERP system or a virtual simulation condition by a user, loading a loaded cargo of a loading platform, a loaded cargo of a cargo container, and a stored cargo of an automated warehouse, and generating 3D coordinates of the loaded cargo container and calculating filtered according to simulation scheduling through the packaging simulator cargo list target coordinates filtered according to simulation scheduling through the packaging simulator.

The loading algorithm through the packaging simulator determines a batch cargo in a cargo container considering a value of a determination function of a lower unit of priority assignment, lower disposal, and avoidance rule, where the determining the batch cargo may include determining double loading prohibition, shipment properties, and a transit location, priority assignment balancing, for disposing a regular cargo in a lower portion and an irregular cargo in an upper portion, solid/heavy weight balancing, for preferentially disposing a solid and heavy weighted cargo at a lower portion and calculating whether the disposed cargo is broken down.

The digital twin-based automated logistics facility operation method may further include, after receiving the loading sequence result value, re-calculating the loading sequence result value, and instructing an automated warehouse release and loading work command in a virtual environment, so as to control a logistics work of the actual logistics facility mirrored based on the virtual environment according to the instruction through the DT server.

The digital twin-based automated logistics facility operation method may further include, after the controlling the logistics work, monitoring an operation state the actual logistics facility through mirroring with the CPS mode and identifying whether the loading work is completed, logging the identified loading work result (OK/NG) into a DB of the DT server, and outputting a loading sequence report in a simulation based on a cargo log and a time chart of an object logged in the DB or playing a black box image in the form of animation.

The loading information may include at least one piece of information among a cargo entering/releasing schedule of an aircraft or a ship, sequence, types, and sizes of available cargo containers, the cargo-entered state within information and an automated warehouse reservation cargo of the ERP, a real-time loaded status of the cargo container.

### BRIEF DESCRIPTION OF THE DRAWINGS

FIG. 1 schematically shows a configuration of a digital twin-based automated logistics facility operation system according to an embodiment.

FIG. 2 is a schematic view showing an example of facility operation of a logistics terminal according to an embodiment.

FIG. 3 is a block diagram schematically showing a configuration of a DT server according to an embodiment.

FIG. 4 is a flowchart showing an automated logistics facility control method using a DT client according to an embodiment.

FIG. 5 schematically shows a concept of a task parser according to an embodiment.

FIG. 6 shows an example of task parser/emulator conversion an automated warehouse according to an embodiment.

FIG. 7 shows an example of task parser/emulator conversion a transport robot according to an embodiment.

FIG. 8 shows an example of deriving virtual facility object time chart depending on various modes according to an embodiment.

FIG. 9 shows a configuration of a packaging simulator according to an embodiment.

FIG. 10 shows an example of simulation condition generation UI of a DT client according to an embodiment.

FIG. 11 shows a loading algorithm utilizing a packaging simulator according to an embodiment.

FIG. 12 shows a cargo container 3D coordinates and cargo dimension pivot state according to an embodiment.

FIG. 13 shows a batch cargo overlap inspection method according to an embodiment.

FIG. 14 shows calculation of weight/loading rate and loading sequence of cargos, and a coordinate logging method according to an embodiment represent.

FIG. 15 shows an example of utilizing raw data of result output module according to an embodiment.

### DETAILED DESCRIPTION

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Throughout the specification, unless explicitly described to the contrary, the word “comprise” and variations such as “comprises” or “comprising” will be understood to imply the inclusion of stated elements but not the exclusion of any other elements. In addition, the terms “unit”, “-er”, “-or”, and “module” described in the specification mean units for processing at least one function and operation, and can be implemented by hardware components or software components and combinations thereof.

Further, the control logic of the present disclosure may be embodied as non-transitory computer readable media on a computer readable medium containing executable program instructions executed by a processor, controller or the like. Examples of computer readable media include, but are not limited to, ROM, RAM, compact disc (CD)-ROMs, magnetic tapes, floppy disks, flash drives, smart cards and optical data storage devices. The computer readable medium can also be distributed in network coupled computer systems so that the computer readable media is stored and executed in a distributed fashion, e.g., by a telematics server or a Controller Area Network (CAN).

The present disclosure will be described more fully hereinafter with reference to the accompanying drawings, in which exemplary embodiments of the disclosure are shown.

The terminology used herein is for the purpose of describing particular embodiments only and is not intended to be limiting of the present disclosure. As used herein, the singular forms are intended to include the plural forms as well, unless the context clearly indicates otherwise.

Throughout the specification, terms such as first, second, “A”, “B”, “(a)”, “(b)”, and the like will be used only to describe various elements, and are not to be interpreted as limiting these elements. These terms are only for distinguishing the constituent elements from other constituent elements, and nature or order of the constituent elements is not limited by the term.

In this specification, it is to be understood that when one component is referred to as being “connected” or “coupled” to another component, it may be connected or coupled directly to the other component or be connected or coupled to the other component with a further component intervening therebetween. In this specification, it is to be understood that when one component is referred to as being “connected or coupled directly” to another component, it may be connected to or coupled to the other component without another component intervening therebetween.

Throughout the specification, the terms used herein are only used to describe certain embodiments and are not intended to limit the present disclosure. Singular expressions are intended to include plural forms as well, unless the context clearly dictates otherwise.

In addition, it is understood that one or more of the following methods or aspects thereof may be carried out by at least one controller. The term “controller” may refer to a hardware device including a memory and a processor. The memory is configured to store program instructions, and the processor is specifically programmed to execute the program instructions to perform one or more processes which are described further below. The controller may control operations of units, modules, components, devices, or the like, as described herein. In addition, it is understood that the following methods may be carried out by an apparatus including the controller as well as one or more other components, as recognized by those skilled in the art.

Now, a digital twin-based automated logistics facility operation system and method according to embodiments will be described in detail with reference to the drawings.

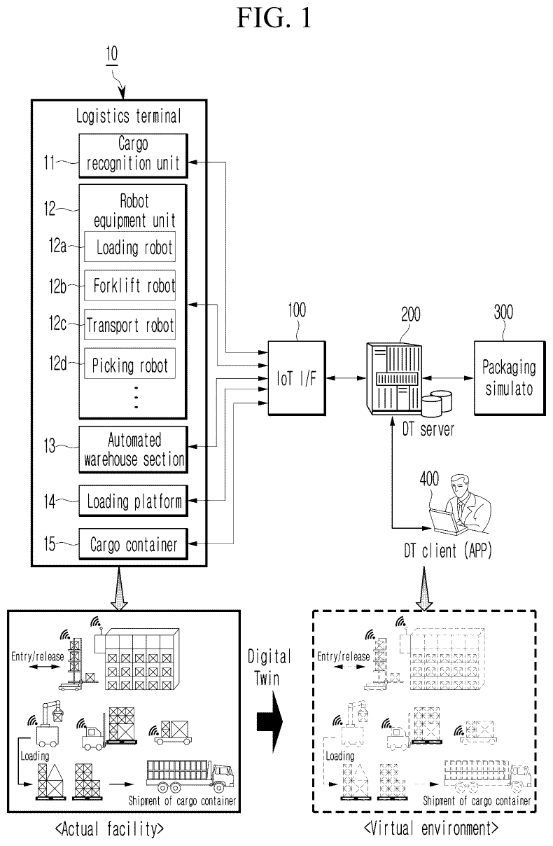

FIG. 1 schematically shows a configuration of a digital twin-based automated logistics facility operation system according to an embodiment.

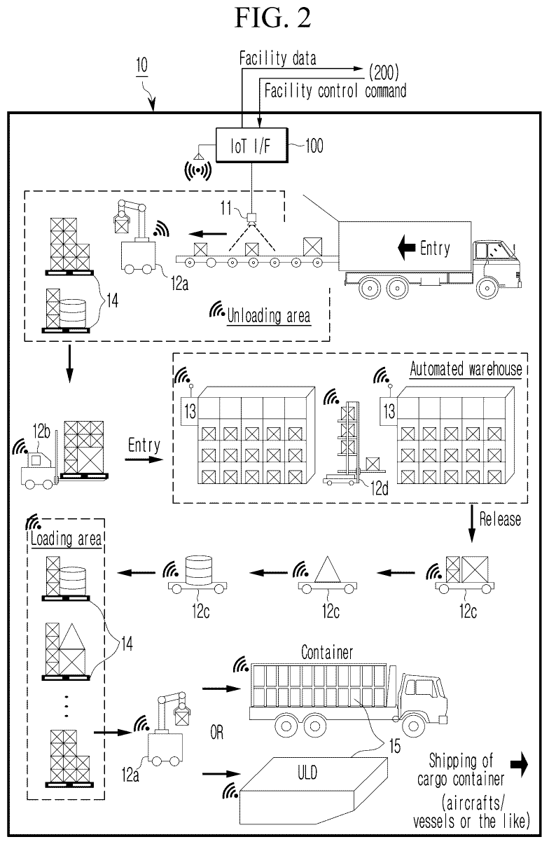

FIG. 2 is a schematic view showing an example of a facility operation of a logistics terminal according to an embodiment.

Referring to FIG. 1 and FIG. 2, digital twin-based automated logistics facility operation system according to an embodiment may include Internet of Things interface (IoT I/F) 100 configured to support heterogeneous communication protocols with respect to various automated logistics facilities 11, 12, 13, 14, and 15 operated in a logistics terminal 10 and collect facility data in real time; a digital twin (DT) server 200 configured to mirror the facility data of the actual (real environment) logistics facilities 11, 12, 13, 14, and 15 and a virtual environment according to the facility data uploaded from the IoT I/F 100; a packaging simulator 300 configured to derive an optimal cargo deployment sequence and disposal location within a designated space, through a loading algorithm (loading stack rule) utilizing the facility data of the DT server 200; and a DT client 400 capable of commanding a loading sequence of the cargo matching a packaging simulation result and an optimal loading work within the designated space (container/ULD or the like). Here, the facility data may include state information on the logistics facility operated in the logistics terminal 10. For example, the state information on the logistics facility may include at least one of a type (model), a unique identification information (ID), a number, a location, an operability, and an operating state, of the facility.

According to an embodiment, the IoT I/F 100 is located at a side toward the logistics terminal 10, however, the DT server 200, the packaging simulator 300 and the DT client 400 may be located at any remote place where communication with the logistics terminal 10 is enabled, without being limited to be placed at the logistics terminal 10.

The logistics terminal 10 according to an embodiment may be applied with a logistics platform in which various logistics items that can be transported by aircrafts or vessels are received, stored, released according to a schedule, and then shipped. The logistics terminal 10 according to still another embodiment may be applied with a logistics system in which loading of received components and automatically storing and releasing of produced products are enabled within a smart factory linked with an enterprise resource planning (ERP) or a manufacturing execution system (MES).

The logistics terminal 10 may operate various logistics facilities including a cargo recognition unit 11, a robot equipment unit 12, an automated warehouse 13, a loading platform 14 and a cargo container 15, or the like.

The cargo recognition unit 11 may measure unique identification information (hereinafter, referred to as “cargo ID”), volume (including the shape) and weight, or the like of the received cargo, by using various measurement devices. For example, the cargo recognition unit 11 may recognize the cargo ID from a smart tag (e.g., barcode, QR code, RFID, NFC, or the like of the received cargo, and may measure a cargo volume, a weight, and a 3D point cloud through a 3D vision connected to a conveyor. At this time, the cargo recognition unit 11 may generate a 3D mesh modeling file based on the cargo ID, the cargo volume, the weight and 3D point cloud.

The IoT I/F 100 may upload the recognized cargo information to a DB table of the DT server 200, together with the 3D mesh modeling file. In addition, the IoT I/F 100 may share the cargo information by transmitting it to the ERP configured to manage entry/release reservation information of the cargo.

The robot equipment unit 12 may include a loading robot 12a, a forklift robot 12b, a transport robot 12c, and a picking robot 12d, or the like, for handling the cargo, and all the robots may include a sensor and a IoT communication means for detecting surroundings.

The loading robot 12a may grip the cargo and load it to the designated space (location). For example, the loading robot 12a may load the cargo on the loading platform 14 or load it in a space within the cargo container 15. The loading robot 12a may grip the cargo and load it to a designated location through an articulated manipulator and a gripper according to the received command.

The forklift robot 12b may lift the loading platform 14 on which the cargos are loaded by using a fork, and transport it to the designated location (e.g., loading area). In addition, the forklift robot 12b may directly load the cargo in a state loaded on the loading platform 14 in the cargo container 15.

The transport robot 12c may load at least one cargo in an upper portion, and transport it to the designated location. For example, the transport robot 12c may transport the received cargo to the automated warehouse 13 or transport the release cargo to the loading area. The transport robot 12c may include at least one of an autonomous mobile robot (AMR) and an automated guided vehicle (AGV).

The picking robot 12d may serve to pick or release the cargo from the automated warehouse 13 of a warehouse rack structure according to the received command. The picking robot 12d may load a plurality of cargos in a multi-stage structure, and input the cargo into or retract the cargo from a cell space of the automated warehouse 13 through lifting/lowering and forward/backward actuators.

In addition, the robot equipment unit 12 may further include, generally, various additional equipment, such as a stacker crane, a crane, a fork actuator, or the like, that can be utilized by being installed in the automated warehouse of the logistics terminal 10.

The automated warehouse 13 may store the cargo in the cell space of a multi-layer structure and may identify the real-time cargo storing information through a sensor and transmit the identified information to the IoT I/F 100. The cargo storing information may include at least one of the cargo ID, entry date, entry sequence, and an idle warehouse rack location. The sensor may include at least one of an IoT sensor, a vision sensor, an infrared sensor, and a piezoelectric sensor, and may detect whether the cargo is to be stored.

The automated warehouse 13 may identify the real-time cargo storing information and the idle cell space for each cell location based on the cargo picking and release information of the picking robot 12d. The automated warehouse 13 may include a warehouse controller configured to automate all works such as entry/release, management, picking, classification, or the like of the cargo, by utilizing peripheral equipment and sensors. The loading platform 14 may have a forklift pick-up structure and a cargo loading space of a pallet structure.

The loading platform 14 may measure the cargo loading information through a unique loading platform ID and a sensor and transmit the measured information to the IoT I/F 100. The cargo loading information may include the cargo ID, weight, and loading space information of the loaded cargo.

The cargo container 15 may include a container and a unit load device (ULD) capable of loading the cargo of a large amount, and may have a size and shape that can be shipped depending on a transport vehicle such as a vessel and/or an aircraft.

The same as the loading platform 14, the cargo container 15 may measure the cargo loading information through the unique ID (hereinafter, referred to as a cargo container ID) and the sensor and transmit the measured information to the IoT I/F 100.

The IoT I/F 100 may have a protocol compatible with a control means of each logistics facility, and may upload logistics information required for the DT server 200 to the DB table.

The DT server 200 may be a center system for the digital twin-based automated logistics facility operation, and may serve to relay data transmission/reception between the IoT I/F 100, the packaging simulator 300 and the DT client 400.

The DT server 200 may link a cyber-physical systems (CPS) mode of the virtual environment mirrored with the logistics terminal 10 based on a digital twin and a control function of a simulation mode of predicting operation efficiency according to modifying of facility operation condition (e.g., number, location, type, or the like of the equipment) of the virtual environment through the packaging simulator 300 to the DT client 400 in the form of a switching structure.

The DT client 400 may be implemented as an application program (APP) for the purpose of supporting the logistics terminal operation state (current status) monitoring of the user and the cargo loading work simulation for each condition through the DT server 200. In addition, the DT client 400 may mean a user terminal in which a corresponding APP is installed. The corresponding user terminal (i.e., the DT client) may be a computer (PC), a laptop, a tablet, a smart phone, or the like, of various logistics item managers, and may be remotely used at any time and place.

The DT client 400 may control an operation state of the logistics facility 10 at a place remote from an on-site of the logistics terminal 10 through the simulation mode and the CPS mode of the DT server 200.

For example, the DT client 400 may command an entering work, a releasing work and a loading work of the designated cargo by being linked with the DT server 200. The entering work may include a series of processes for loading the received cargo on the loading platform, and transporting and picking it to the automated warehouse 13. The releasing work may be a work for releasing the cargo from the automated warehouse 13. The loading work may include a work for loading the cargo in the loading platform 14 of the work area and/or the designated space of the cargo container 15.

In addition, the DT client 400 may command an instruction for a loading sequence, a releasing sequence, and an optimal loading work within the designated space (container/ULD or the like) of the received cargo through the loading algorithm.

In addition, the DT client 400 may reproduce (replay) a black box image as a simulation based on the cargo log and a time chart of an object by logging a loading work result into a DB 240.

In a digital twin-based automated logistics facility operation system according to an embodiment, the IoT I/F 100 is located at a side toward the logistics terminal 10, however, the DT server 200, the packaging simulator 300 and the DT client 400 may be located at a remote place where communication with the logistics terminal 10 is enabled, without being limited to be placed at the logistics terminal 10. In addition, the packaging simulator 300 may be implemented in an independent computer system or integrated to the DT server 200. Hereinafter, a detailed configuration of the DT server 200 according to an embodiment will be described.

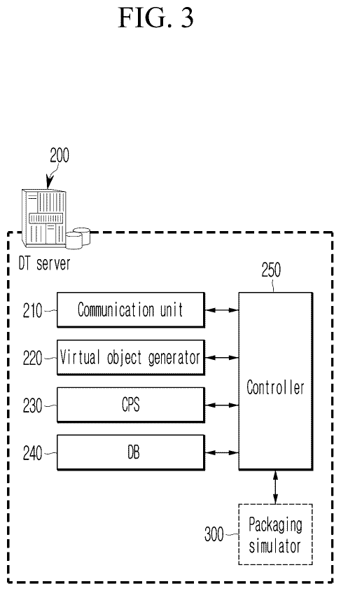

FIG. 3 is a block diagram schematically showing a configuration of the DT server according to an embodiment.

Referring to FIG. 3, the DT server 200 according to an embodiment may include a communication unit 210, a virtual object generator 220, cyber-physical systems (CPS) 230, database (DB) 240, and a controller 250. Here, the DT server 200 may further include the packaging simulator 300.

The communication unit 210 may transmit and receive data required for the operation of digital twin-based automated logistics facility through wired/wireless communication means.

The communication unit 210 may relay data transmission/reception between the IoT I/F 100, the packaging simulator 300 and the DT client 400.

As an example, the communication unit 210 may relay various data as shown in [transmitting/receiving relay table of the DT server] below.

TABLE 1
Transmitting/receiving relay data table of the DT server

| Target | | Send to DT server | Receive from DT server |
|---|---|---|---|
| IoT | Robot | robot ID, location, moving speed, | |
| I/F | equipment | deceleration, acceleration, a lidar | |
| | unit | sensor, spin turn, driving along curved | |
| | | line, lift up/down state, applied load, | |
| | | nodes (origin, destination) | |
| | Cargo | mesh modeling data file, cargo ID, | |
| | recognition | transport vehicle information, special | |
| | unit | shipment attributes, a water volume, a | |
| | | square volume, weight, whether cargo | |
| | | barcode is broken down, piece, | |
| | | generated time, regularity | |
| | Automated | cargo ID, cell information, picking | release command (reverse |
| | warehouse | robot work state, cargo | operation value of loading |
| | | entering/releasing, stacker crane state, | sequence) |
| | | fork work state, cargo detection for | |
| | | each loading platform, encoder for | |
| | | each stacker axis, C/T for each cell, | |
| | | conveyor speed, rack address | |
| | Loading | current coordinates, carriage location | loading platform release |
| | robot | value, speed, starting load ratio, | location, loading location |
| | | component detecting sensor, | within cargo container |
| | | loading/unloading | (ULD) |

| DT client | transport vehicle cargo container | facility information received |
|---|---|---|
| | (container/ULD) number/ | from each equipment, |
| | sequence/type transport vehicle | packaging simulation result |
| | entry/release schedule, reserved | |
| | information of cargo, whether | |
| | operation detection of virtual facility | |
| | is triggered (user's control | |
| | instruction) | |
| Packaging | coordinates for each cargo ID, total | ERP reserved cargo |
| simulator | weight, total volume, total loading | information, work cargo |
| | rate, loading time, required work time | container, loading platform |
| | | information, received-cargo |
| | | information within |
| | | automated warehouse |

In the above Table 1, information transmitted to the DT server 200 by the robot equipment unit, the cargo recognition unit, the automated warehouse, and the loading robot of the IoT I/F 100 may be included in the facility data described above.

The virtual object generator 220 may generate the virtual object based on regular and irregular cargo information including the 3D mesh modeling file and the facility data of the logistics terminal 10 collected from the IoT I/F 100. The virtual object may include one or more facility objects and the cargo object.

The CPS 230 may implement a mirrored CPS mode by disposing the virtual object within the virtual environment simulating the logistics terminal 10 and processing real-time synchronization on the facility data of an actual environment.

The CPS 230 may convert the facility data collected in real time at the time of the CPS mode into a motion sequence within the virtual environment and display the converted motion sequence to the user in the virtual environment mirroring animation. In addition, the CPS 230 may output various meaningful facility operation indicators by analyzing a difference in the simulation result when the cargo of the same condition is operated in the simulation.

The DB 240 may store various program and data required for an operation of the DT server 200, and may convert the data generated according to the operation into a DB. The DB 240 may manage various DB tables generated through the conversion into the DB.

For example, the DB 240 may manage the DB tables respectively corresponding to the facility data, logistics information, and simulation result.

The controller 250 may be a central processing device configured to control an overall operation of the DT server 200 for operating a digital twin-based automated logistics facility according to an embodiment.

The controller 250 may register the DT client 400 and store the registered DT client in the DB 240, and may grant a control authority for operating the automated logistics facility of the logistics terminal 10 to the DT client 400 connected through user authentication.

The controller 250 may transfer data enabling driving of the object in the virtual environment simulating an actual logistics facility 10 according to a request of the DT client 400. At this time, the data transferred from the controller 250 may include the facility data synchronized with the actual logistics facility 10 in real time according to the CPS mode the request of the DT client 400 and two types of task parser signals simulating information transmitted/received between the IoT I/F 100 and the logistics facility 10 according to the simulation mode request.

The controller 250 may load the cargo information, the modeling shape information, the loading space information, or the like, measured according to the simulation mode request to the packaging simulator 300. Accordingly, the packaging simulator 300 may derive the optimal cargo deployment sequence and the deployment location through the loading algorithm using the loaded information and transfer the derived information to the controller 250. Here, the optimal cargo deployment may mean a deployment state that can load maximally many cargos in a limited space while maintaining balancing of the volume and weight of cargos.

The controller 250 may transfer the optimal cargo deployment sequence and the deployment location derived as the packaging simulator result to the DT client 400. Accordingly, the DT client 400 may transmit the logistics facility control instruction according to the optimal cargo deployment sequence and the deployment location to the IoT I/F 100 through the DT server 200.

For example, the controller 250 may transmit the cargo release order from the automated warehouse 13 to the IoT I/F 100 by reversing the loading sequence according to the logistics facility control instruction of the DT client 400. In addition, the IoT I/F 100 may transfer the cargo release commands corresponding to the automated warehouse 13 and the robot equipment unit 12, respectively.

The IoT I/F 100 may map the cargo ID and the loading platform ID of the loading area that match with the packaging simulation result and command the loading area cargo pick-up to the loading robot 12a, so as to load the picked-up cargo to a designated loading location of the designated cargo container 15. At this time, the automated warehouse 13 and the robot equipment unit 12 having received the cargo release command may perform releasing, moving, and loading work of the designated cargo, and may record the performed actual work result and the history. For example, the work result may be facility operation log information recorded in time series, and may be transferred to the DT server 200 through the IoT I/F 100 to be logged in the DB 240.

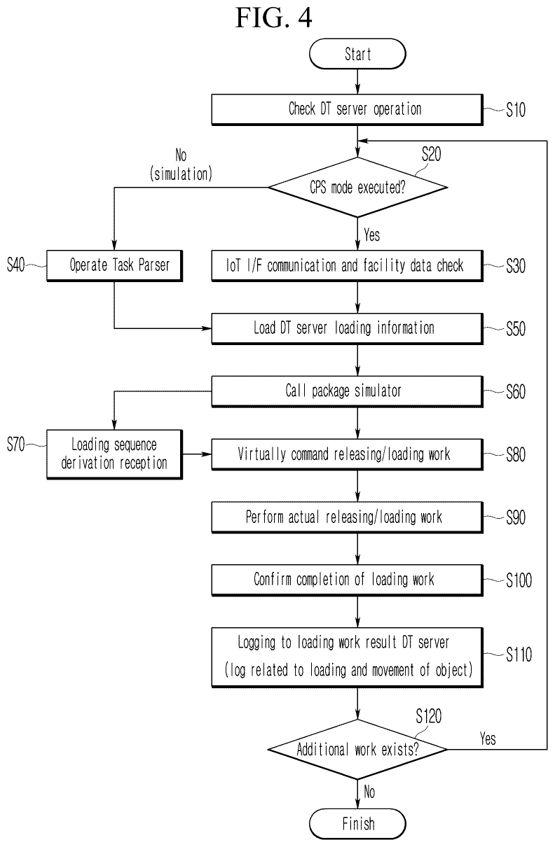

Meanwhile, FIG. 4 is a flowchart showing the automated logistics facility control method using the DT client according to an embodiment.

Referring to FIG. 4, since the DT client 400 according to an embodiment operates based on the DT server 200, the operation state may be checked by being connected to the DT server 200, at step S10. At this time, when the user authentication of the DT client 400 is successful based on the registered information, the DT server 200 may provide the automated logistics facility control function described later.

The DT client 400 may select whether the CPS mode or the simulation mode is to be executed during a normal operation of the DT server 200, at step S20.

When the user selects the CPS mode at the step S20, (S20—Yes), the DT client 400 may execute the CPS mode to communicate with the IoT I/F 100 and check the facility data, at step S30. In addition, the DT client 400 may be provided with a digital twin service based on the facility data synchronized with the actual logistics facility 10 in real time according to the CPS mode.

On the other hand, at the step S20, the user may not select the CPS mode or select the simulation mode (S20—No). At this time, the DT client 400 may execute the simulation mode, to request an operation of the task parser for generating a work command, at step S40.

When a preparation-state required for each mode that was previously executed is completed, the DT client 400 may load the loading information of the DT server 200 according to a work command generating processor of the task parser, at step S50. Here, the loading information may include the cargo entering/releasing schedule, sequence, types, and sizes of available cargo containers (container and unit load device (ULD)), the cargo-entered state within the automated warehouse and the cargo reservation information of the ERP, an intermediate (real time) loaded status of the cargo container, or the like, of the cargo transport vehicle (aircraft, vessel, or the like). That is, the loading information may include information required for loading of the cargo having entered into the logistics terminal or releasing of the cargo stored therein.

The DT client 400 may call the packaging simulator 300 according to loading of the loading information, at step S60, and may receive an optimal loading sequence result value derived through the loading algorithm-based simulation, at step S70.

The DT client 400 may re-calculate the receive optimal loading sequence result value and instruct the automated warehouse release and loading work command in the virtual environment, at step S80. At this time, the DT client 400 may control the logistics work of the actual logistics facility mirrored (synchronized) based on the virtual environment according to the instruction through the DT server 200, at step S90. Accordingly, according to the work command in the virtual environment, the DT server 200 may control the actual logistics facility and mirror whether it is completed to the DT client 400 to be real-time synchronized.

The DT client 400 may monitor operation state the actual logistics facility through mirroring with the CPS mode and may identify whether the loading work is completed, at step S100.

In addition, the DT client 400 may log the identified loading work result (OK/NG) into the DB 240 of the DT server 200, at step S110. At this time, the DT client 400 may convert the logistics facility automatic log information including at least one of the cargo loading sequence and location coordinates of each cargo, a derivation time, a volume efficiency, a weight, special shipment attributes values, and a time chart based on time trigger-on of the object into a DB, and store the converted DB.

Thereafter, the DT client 400 may identify whether there exists an additional work, at step S120, when the additional work exists (S120—Yes), it may return to repeat the above processes. For example, in the case of the CPS mode, it may be repeated until the user's termination, and in the case of the simulation mode, it may be repeated until all the requested simulations are performed.

On the other hand, when the additional work does not exist (S120—No), the DT client 400 may terminate the program.

The automated logistics facility control method described above took the DT client 400 on the side of the user, operated based on the DT server 200, as the subject. However, an embodiment is not limited thereto, and the DT server 200 providing the digital twin-based automated logistics facility operation service to one or more DT clients 400 may be selected as the subject. That is, the DT server 200 may authenticate the connection of the registered DT client 400 and selectively provide the CPS mode and the simulation mode. In addition, by receiving the entering work and releasing work command of the designated cargo through the task parser of the DT client 400 and transferring it to the IoT I/F 100, an operation of the actual logistics facility 10 may be controlled.

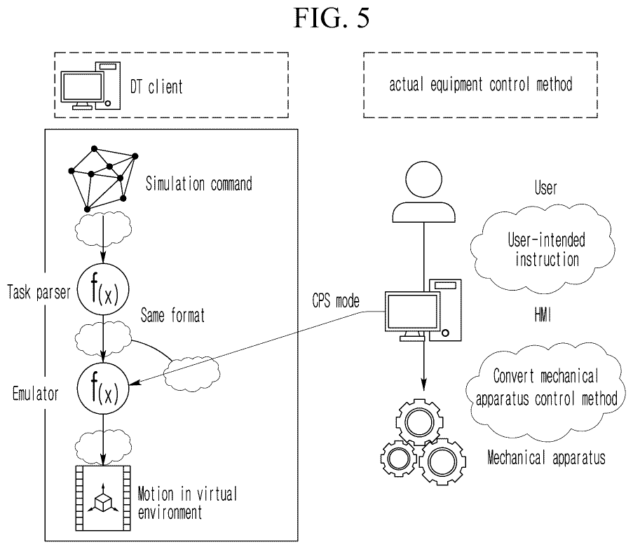

Meanwhile, FIG. 5 schematically shows a concept of the task parser according to an embodiment.

Referring to FIG. 5, the task parser may be a core concept enabling mode switching of the DT client 400, and have various forms of conversion formula depending on the type of actual equipment.

The logistics facility 10 inside the logistics terminal 10 receives the user's intention (instruction) through Human-Machine Interface (HMI), and through an internal software (S/W) algorithm, convert it into a control signal for the corresponding mechanical apparatus, to control the apparatus.

At this time, in the CPS mode, through the IoT I/F 100 described above, conversion may be made according to heterogeneous communication protocols of each equipment and may be transferred to the DT server 200 in the processed data format. However, the motion sequence of the virtual environment may operate in a different syntax from the actual logistics facility 10, and the user's intention may also be defined by the DT physics engine.

Therefore, the task parser may perform a work of converting the user's intention (instruction) into a signal in the same format as the IoT I/F 100, so as to convert the facility data of the logistics facility 10 to the same DB table within the DT server 200 and manage it. In addition, the signal defined in the same format may be defined in the physics engine in the form of the motion sequence by the emulator of the DT client 400, so as to represent the motion similar to the actual equipment to the user.

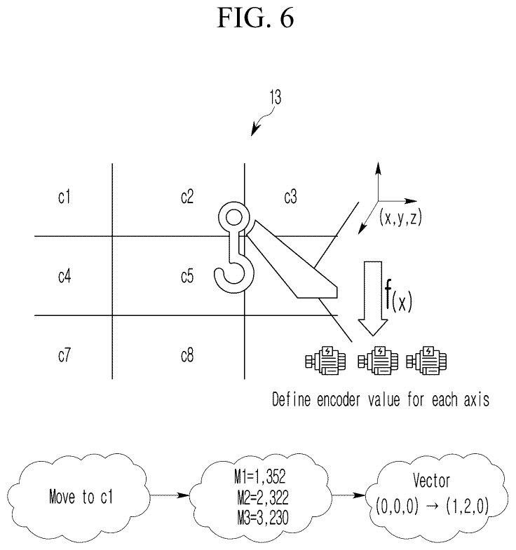

For example, FIG. 6 shows an example of task parser/emulator conversion of the automated warehouse according to an embodiment represent.

Referring to FIG. 6, a scenario is assumed in which, in the automated warehouse 13, a virtual simulation instruction or an instruction on an actual HMI requests releasing of the cargo in a first cell c1.

At this time, the primary command of the stacker crane installed in the automated warehouse 13 may be moving to a location of the first cell c1. However, the movement of the stacker crane in the actual equipment may be received as an encoder rotation value applied to 3-axis (x, y, z) servo-motors.

Therefore, the task parser may convert the command of moving to the location of the first cell c1 into the form of the task parser format in the virtual environment. In addition, the emulator may implement animation by defining the movement command as vector value changes in the physics engine.

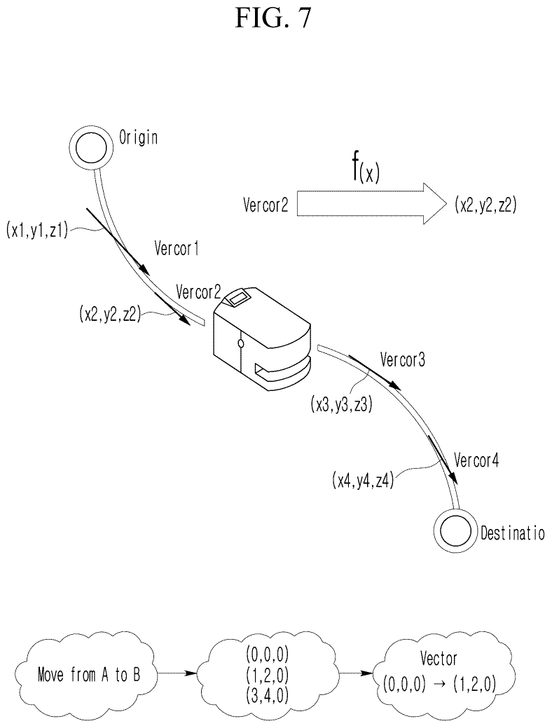

In addition, FIG. 7 shows an example of task parser/emulator conversion of the transport robot according to an embodiment.

Referring to FIG. 7, a scenario is assumed in which moving from an origin A to a destination B is commanded to the AMR, which is one of the transport robots. In the CPS mode, a motion may be defined by tracking of the current location value of the AMR. At this time, the task parser may re-define the node-type definition of origin-destination (A to B) movement into a coordinate path, and the emulator may implement the same animation as the operation-state of the actual AMR with vector movement within the virtual environment.

TABLE 2
Transmitting/receiving relay data table of the DT server

| | Item | Trigger return | Reference for determining clock value |
|---|---|---|---|
| 2 | unmanned | [MOV] [CHA] | On during movement/when the motion |
| | forklift | | sequence such as forklift operated; Off |
| | | | when stopped |
| 3 | volume/weight | [MEA] [IN] [OUT] | On when conveyor is operated or cargo |
| | measurement | | detecting sensor or measurement is being |
| | | | performed; |
| | | | Off when measurement terminated and |
| | | | conveyor not operated and cargo not |
| | | | detected and abnormal non-operation |
| 4 | AMR for entry | [MOV] [CHA] [LIF] | Needs to determine for management for |
| | into warehouse | | each AMR or entire AMR unit management |
| | | | ON when AMR movement/spin turn/ |
| | | | elevating and/or lowering lift/charger |
| | | | movement |
| | | | Off when charging/stopped state/cargo |
| | | | unloaded state/abnormality occurrence |
| 5 | AMR for | | |
| | release from | | |
| | warehouse | | |
| 6 | | [MOV] [IN] [OUT] | Whether conveyor to operate for |
| | | | entry/release or the stacker crane motion |
| | | | operation is On |
| 7 | | [MOV] [IN] [OUT] | |
| 8 | ULD (Unit | [WORK] | Final selection of cargo (represented at a |
| | Load Device) | | corresponding time point not for time |
| | or container | | having continuity) |
| | standby time | | |

Table 2 above represents a reference example of determining whether an object modeled after each actual equipment is operating. This serves as a reference for classifying the time when equipment is working and the time when it is not working within the virtual environment.

The same as the basic concept of the task parser, in both the CPS mode and the simulation mode, the history log on the virtual environment may also be defined and recorded as the same DB table. Therefore, it is possible to reproduce this as a black box and simulate it under the same conditions.

For example, the DT client 400 can provide a time chart that can analyze the work efficiency of the actual equipment based on the DB table. In addition, the black box can be reproduced by using a simulation algorithm that directly utilizes the above history log, and can be provided as basic data for analysis to improve the consistency of the simulation algorithm.

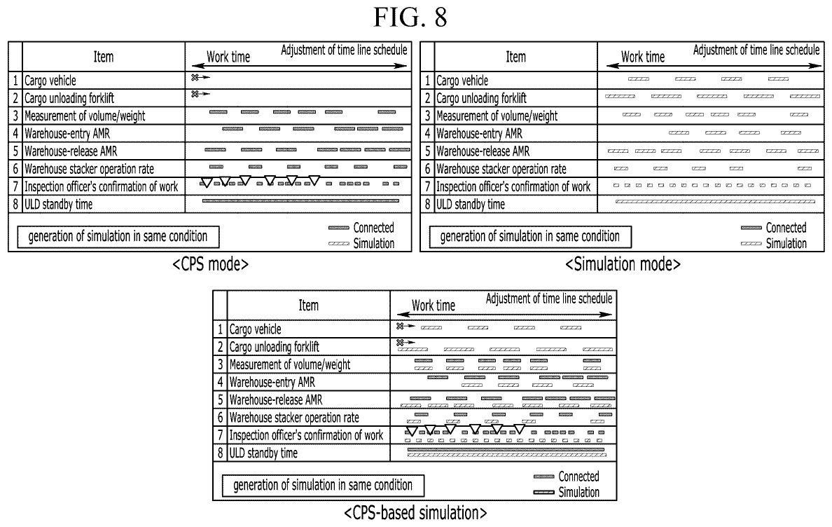

FIG. 8 shows an example of deriving virtual facility object time chart depending on various modes according to an embodiment.

Referring to FIG. 8, the DT client 400 shows a user interface (UI) screen showing whether the object is in motion, for each of the CPS mode, the simulation mode, and the CPS-based simulation based on the above Table 2.

In the CPS mode, the time performed by each automated equipment may be represented with respect to information that enables actual equipment-based tracking. At this time, the downtime or standby time is expressed in a different way (e.g., in a different color or not displayed) than the operation so that the user can identify it.

In the above simulation mode, the presence or absence of movement of the object is expressed in the same manner as above through the motion sequence algorithm.

The above CPS-based simulation is a simulation result that appears when the cargo under the same conditions is operated in the simulation. During the initial development or improvement verification stages of the system, the two modes may have low consistency and thus different results. This can provide managers with basic data for difference analysis, thereby achieving goals such as improving algorithm consistency and improving facility operation indicators.

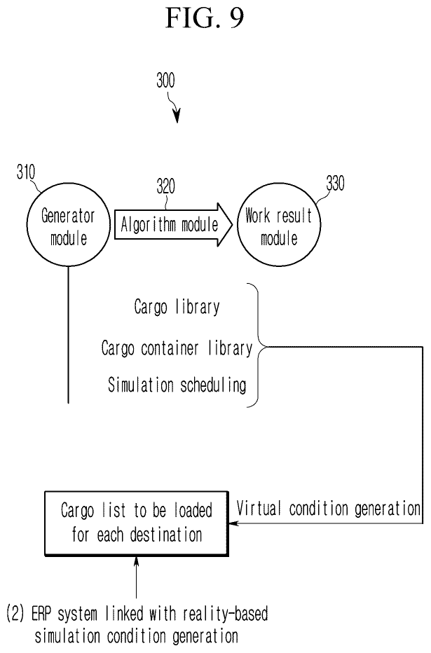

Meanwhile, the modularized structure the packaging simulator 300 and the loading algorithm utilizing the same will be described in detail with reference to the drawings. First, FIG. 9 shows a configuration of the packaging simulator according to an embodiment represent.

Referring to FIG. 9, the packaging simulator 300 according to an embodiment may be configured as three modules including a generator module 310, the loading algorithm module 320, and a work result module 330.

Referring to FIG. 9, the generator module 310 may have a backend DB structure including three conditions of the cargo library, the cargo container library, and simulation scheduling, and the library may be continuously appended.

The cargo library can be modified into various forms according to the customer's requests.

The cargo library may have, as its core structure, basic columns of cargo ID, file name for 3D modeling mapping, water volume, square volume, weight, dimensions (WDH), regularity, current location, destination, special shipment attributes, or the like.

Data can be manually added to the cargo library, and an additional library may be configured by accumulatively updating previous histories through the cargo recognition unit 11 and the ERP system. In addition, the cargo library can create, read, update, and delete (CRUD) the key DB according to the user or the purpose.

The cargo container library can modify the ULD or the container into various forms according to the customer's requests, and may include, as core configurations, cargo ID, file name for 3D modeling mapping, water volume, square volume, and attribute information such as flight.

As the cargo container library, the unit load device (ULD) or the container type is determined according to the designated flight/ship. In addition, the cargo container library can CRUD the key DB according to the user or the purpose.

The simulation scheduling is a DB for regulating conditions, and as needed, may be generated by filtering by user UI or prepared in advance for large-scale simulation.

The simulation scheduling may include transit locations, destinations, times, logistics lines, or the like. The simulation scheduling can CRUD the key DB according to the user or the purpose.

The generator module 310 may generate the cargo loading list for each destination for virtual-based or reality-based simulation through the above three conditions.

For example, the generator module 310 may generate the cargo list to be loaded for each destination by selectively performing generating a virtual simulation condition by the user or generating the reality-based simulation condition through linking with an upper ERP system having the actual cargo reservation information. The cargo list to be loaded for each destination may be defined in the same DB format as the actual flight/vessel reservation information of the CPS mode. In addition, all DBs, such as the cargo libraries or the cargo list to be loaded for each destination, are constructed in a CURD-capable structure so that they can be created, read, updated, and deleted through the user's DT client 400.

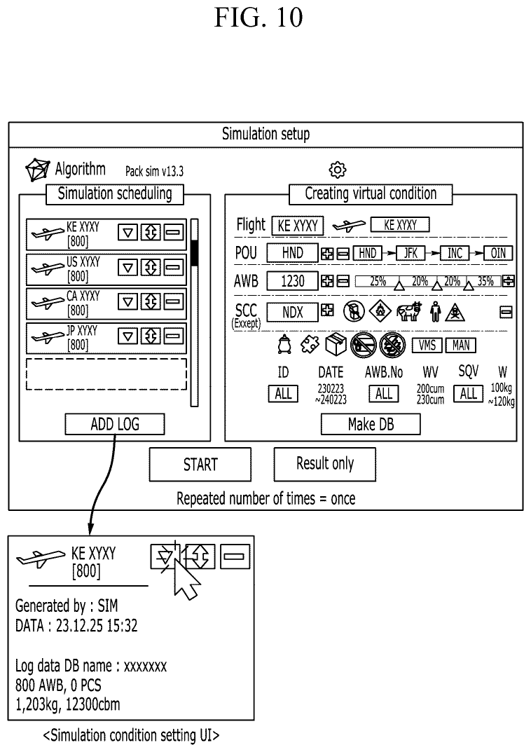

Subsequently, FIG. 10 shows an example of a simulation condition generation UI of the DT client according to an embodiment.

Referring to FIG. 10, a user can create or designate the cargo list to be loaded and the cargo container through virtual schedules and/or condition settings within the library of the packaging simulator 300-based simulation condition generation UI called through the DT client 400. In addition, the user may conduct package simulation by generating or changing schedules and conditions based on previous logs having occurred during operation of the actual logistics terminal through ADD LOG on the DT client 400.

The DT client 400 may be implemented as one or more processors operated by a predetermined program, and the predetermined program may be programmed to derive a work result 130 by performing respective steps of the loading algorithm according to an embodiment.

Therefore, in the flow of the loading algorithm described below, the DT client 400 is taken as a subject, and it may be understood that it may be performed substantially through the packaging simulator 300.

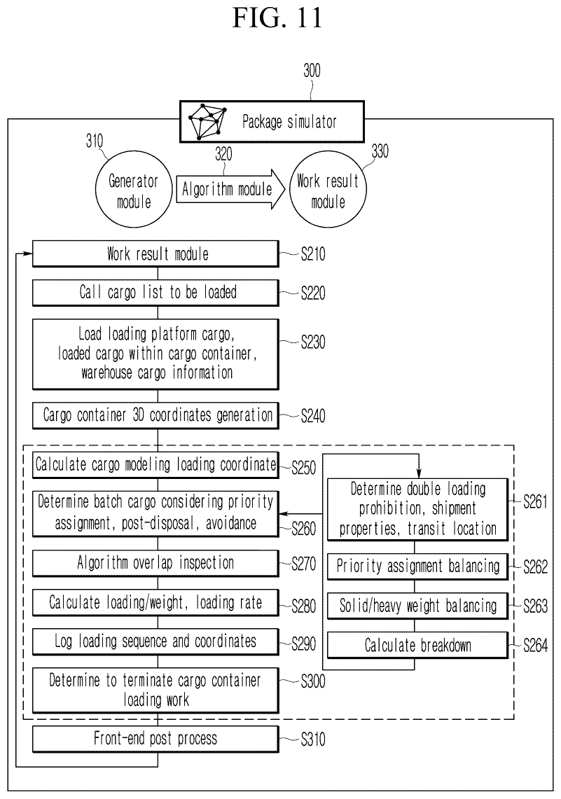

FIG. 11 shows a loading algorithm utilizing a packaging simulator according to an embodiment.

Referring to FIG. 11, the DT client 400 according to an embodiment may call the packaging simulator 300 for the cargo loading algorithm, at step S210. At this time, the DT client 400 may access the DT server 200 to perform the user authentication, and when the authentication is successful, it may call the packaging simulator. In addition, the DT server 200 may execute the packaging simulator 300, according to the call of the DT client 400 that was successful at the user authentication.

Hereinafter, an operation of the packaging simulator 300 by the DT client 400 will be described.

The packaging simulator 300 may generate the cargo list to be loaded, at step S220. As described above, the packaging simulator 300 may selectively generate the cargo list to be loaded for each destination according to the virtual simulation condition by the user or the reality-based simulation condition through linking with the upper ERP system.

The packaging simulator 300 may load the loaded cargo of the loading platform 14, the loaded cargo of the cargo container 15, and the stored cargo of the automated warehouse 13, at step S230. Here, as the cargo container 15, a ULD or a container may be designated depending on the transport vehicle. The loaded cargo of the loading platform 14 and the cargo container 15 may include at least one cargo currently disposed within a corresponding space and a physical space occupied by that cargo.

The packaging simulator 300 may generate 3D coordinates of the loaded cargo container 15, at step S240.

The packaging simulator 300 may calculate optimal coordinates with respect to the cargo list filtered according to the simulation scheduling, at step S250.

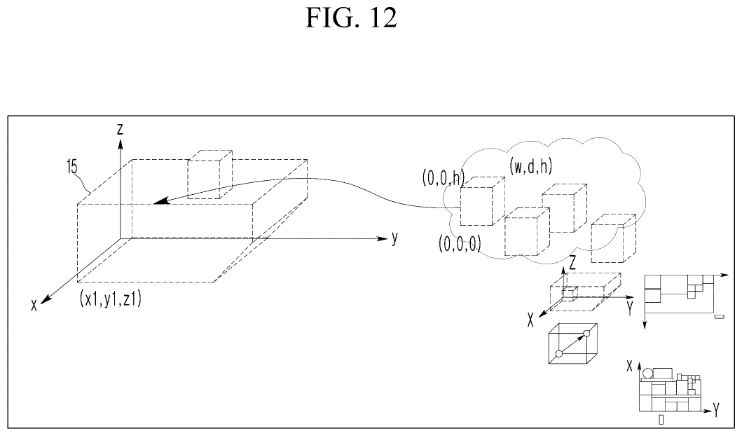

For example, FIG. 12 shows a cargo container 3D coordinates and the cargo dimension pivot state according to an embodiment represent.

Referring to FIG. 12, the packaging simulator 300 may generate 3D point coordinates according to the shape of the cargo container 15 and 3D space coordinate system (x, y, z) formed inside the cargo container. Therefore, the packaging simulator 300 may represent a physical space of the cargo loaded inside the cargo container 15 on the 3D space coordinate system. In addition, the packaging simulator 300 may generate volume coordinates of the loading-target cargo and represent it in 3D.

The packaging simulator 300 may determine a batch cargo inside the cargo container 15 considering a value of a determination function of a lower unit such as priority assignment, lower disposal, and avoidance rule, at step S260. Here, the process of determining the batch cargo may include a step S261 of determining double loading prohibition, shipment properties, and a transit location; a step S262 of priority assignment balancing, in which the regular cargo is disposed in a lower portion and the irregular cargo is disposed in an upper portion; a step S263 of solid/heavy weight balancing, in which a solid and heavy weighted cargo is preferentially disposed in the lower portion; and a step S264 of calculating whether the disposed cargo is broken down.

The packaging simulator 300 may inspect whether a physical space overlap of batch cargos occurs within the cargo container 15, at step S270.

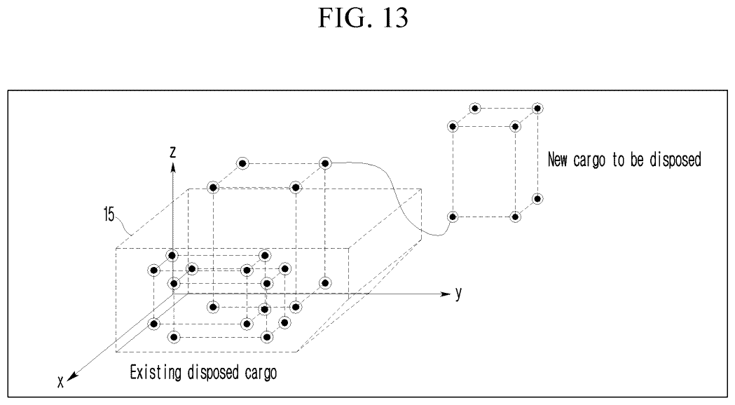

For example, FIG. 13 shows a batch cargo overlap inspection method according to an embodiment represent.

Referring to FIG. 13, whether the existing disposed cargo and a new cargo to be disposed on a 3D space coordinate system (x, y, z) within the cargo container 15 overlap in a physical space may be inspected. When the physical space overlap occurs as the inspection result, the disposal location may be modified.

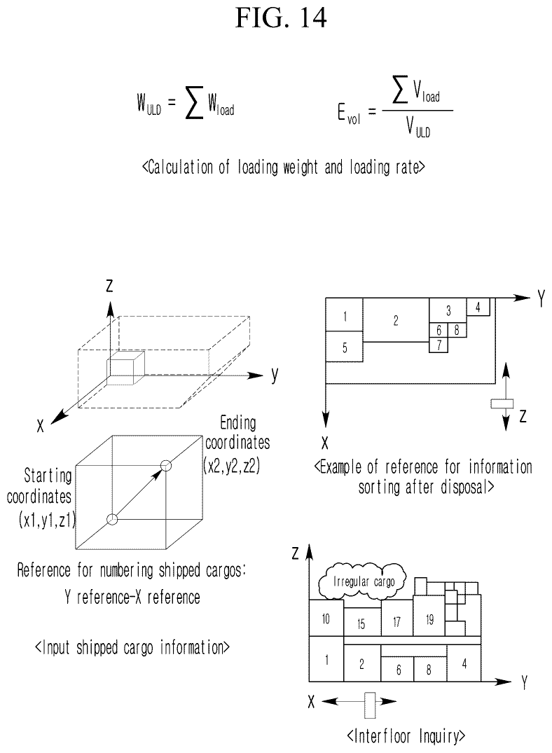

FIG. 14 shows the calculation of the weight/loading rate and the loading sequence of cargos, and a coordinate logging method according to an embodiment represent.

Referring to FIG. 14, the packaging simulator 300 may calculate the loading weight and/or loading rate of the cargo container 15 based on information of a generator library DB, at step S280.

In addition, the packaging simulator 300 may log the loading sequence and coordinates of the cargo disposed inside the cargo container 15, at step S290. At this time, the shipped cargo information may be input based on the numbering of the cargos disposed inside the cargo container 15, and the state information of layer-wise or width-wise loading of the disposed cargo may be graphically processed and provided.

The packaging simulator 300 may inspect whether the logged data matches the work terminating condition of the cargo container 15, and when it matches the work terminating condition, it may determine termination of the loading work, at step S300.

After determining the work termination, the packaging simulator 300 may perform a front-end post process, at step S310. At this time, the gravity and collider properties of individual cargo can be applied in the 3D virtual environment to prevent collisions. In addition, when performing the front-end post process, the packaging simulator 300 may load a modeling file on the front end (virtual 3D physics engine), may arrange numerical coordinate values of batch cargos on the loading algorithm, and may perform cross-checking on unstable loading considering gravity and collider properties, the irregular cargo and the cargo container inspection reference space interference, or the like.

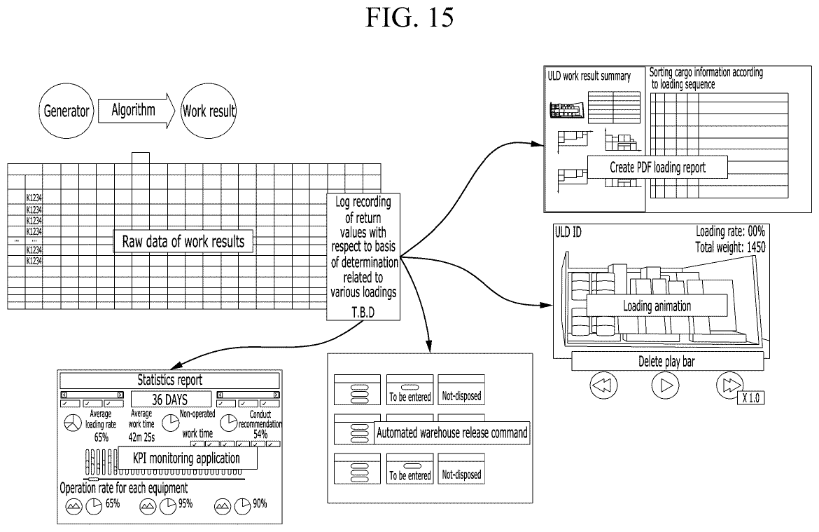

Meanwhile, FIG. 15 shows an example of utilizing raw data of result output module according to an embodiment.

Referring to FIG. 15, the work result module 330 according to an embodiment may generate operation key performance indicator (KPI) statistical data analysis data based on raw data according to the work result of the packaging simulator 300.

At this time, the DT client 400 may output the loading sequence of a specific cargo container 15 designated in the analysis data in the form of electronic documents (e.g., PDF) or paper reports.

In addition, the DT client 400 may display the loading sequence of the specific cargo container 15 in the form of animation through a monitoring program APP.

In addition, the DT client 400 may transfer the loading work command by setting a specific cargo and a disposal location of the cargo container 15 to the loading robot 12a.

In addition, the DT client 400 may analyze the time table and loading result, the operation KPI and external API (weather, news), or the like through multi-neural network deep learning AI algorithm, and derive the result as text through a language model.

In addition, this can be reprocessed and expressed in the form of a virtual human analyzing the current situation and suggesting alternatives using external AI logic such as TTS, conversational motion generation, and virtual human model generation.

As such, according to an embodiment, an integrated system capable of supplementing weak points between virtual-actual realities can be provided, by linking a CPS mode, in which data of the actual logistics terminal and an automated equipment within a virtual environment are synchronized and mirrored in real-time based on a digital twin (DT), and a control function of a simulation mode, in which a virtual condition is modified and predicted, with a switching structure.

In addition, through the linkage between the DT server and the DT client of the digital twin service, an instruction for the loading sequence, a releasing sequence, and an optimal loading work within the designated space (container, ULD, or the like) of the entered cargo may be commanded to the actual logistics terminal in a by remote place, and the work result may be checked.

In addition, by a black box image may be reproduced as simulation based on the cargo log and the time chart of the object by logging the loading work result into DB, and through this, analysis data for improving consistency of the loading simulation algorithm can be provided.

The exemplary embodiments of the present disclosure described above are not only implemented by the apparatus and the method, but may be implemented by a program for realizing functions corresponding to the configuration of the embodiments of the present disclosure or a recording medium on which the program is recorded.

While this disclosure has been described in connection with what is presently considered to be practical embodiments, it is to be understood that the disclosure is not limited to the disclosed embodiments. On the contrary, it is intended to cover various modifications and equivalent arrangements included within the spirit and scope of the appended claims.

What is claimed is:

1. A digital automated logistics facility operation system, comprising:
an interface configured to support heterogeneous communication protocols with respect to various automated logistics facilities operated in a logistics terminal and collect facility data in real time;
a server configured to mirror the facility data of an actual logistics facility and a virtual environment according to the facility data uploaded from the interface;
a packaging simulator configured to derive a cargo deployment sequence and disposal location within a designated space, through a loading algorithm utilizing the facility data of a server; and
a client device capable of commanding a loading sequence of the cargo matching a packaging simulation result and a loading work within the designated space.

2. The system of claim 1, wherein the logistics facility comprises:
a cargo recognition unit configured to measure a cargo ID, volume, weight of the entered cargo through a measurement device;
a robot equipment unit comprising a loading robot, a forklift robot, a transport robot, and a picking robot, configured to handle the cargo;
an automated warehouse configured to store the cargo in a cell space of a multi-layer structure and identify real-time cargo storing information through a sensor and transmit the identified information to the interface;
a loading platform having a forklift pick-up structure and a cargo loading space of a pallet structure; and
a cargo container comprising a container and a unit load device (ULD) capable of loading the cargo of a large amount depending on a transport vehicle.

3. The system of claim 2, wherein the interface is configured to upload a recognized cargo information comprising a 3D mesh modeling file of the cargo through 3D vision to a database table of the server and share the recognized cargo information by transmitting the recognized cargo information to an enterprise resource planning (ERP) configured to manage entry/release reservation information of the cargo.

4. The system of claim 1, wherein the server is configured to link a cyber-physical systems (CPS) mode of the virtual environment mirrored with the logistics terminal and a control function of a simulation mode of predicting operation efficiency according to modifying of facility operation condition of the virtual environment through the packaging simulator to the DT client in the form of a switching structure.

5. The system of claim 4, wherein the client device is configured to control an operation state of the logistics facility at a place remote from an on-site of the logistics terminal through the simulation mode and the CPS mode of the server.

6. The system of claim 5, wherein the client device is configured to command an entering work, a releasing work and a loading work of the designated cargo by being linked with the server.

7. The system of claim 5, wherein the client device is configured to reproduce a black box image as a simulation based on a cargo log and a time chart of an object by logging a loading work result of the cargo into a database.

8. The system of claim 1, wherein the server comprises:
a communication unit configured to relay data transmission/reception between the interface, the packaging simulator, and the client device;
a virtual object generator configured to generate a virtual object based on regular and irregular cargo information comprising a 3D mesh modeling file and the facility data of the logistics terminal collected from the interface;
a cyber-physical systems (CPS) configured to implement a mirrored CPS mode by disposing the virtual object within the virtual environment simulating the logistics terminal and processing real-time synchronization on the facility data of an actual environment;
a database configured to manage database tables respectively corresponding to the facility data, logistics information, and the simulation result; and
a controller configured to transfer data enabling driving of an object in the virtual environment simulating the actual logistics facility according to a request of the client device.

9. The system of claim 8, wherein the CPS is configured to convert the facility data collected in real time at the time of the CPS mode into a motion sequence within the virtual environment and display the converted motion sequence to the user in a virtual environment mirroring animation.

10. The system of claim 8, wherein the CPS is configured to output a meaningful facility operation indicator by analyzing a difference in the simulation result when the cargo of the same condition is operated in the simulation.

11. The system of claim 8, wherein the controller is configured to register the client device and store the registered DT client in the database, and grant a control authority for operating the automated logistics facility of the logistics terminal to the client device connected through user authentication.

12. The system of claim 8, wherein the data transferred by the controller comprises facility data synchronized with the actual logistics facility in real time according to a CPS mode request of the client device and two types of task parser signals simulating information transmitted/received between the logistics facility and the interface according to a simulation mode request.

13. The system of claim 12, wherein:
the controller is configured to load the cargo information, modeling shape information, and loading space information to the packaging simulator according to the simulation mode request;
the packaging simulator is configured to derive the cargo deployment sequence and the deployment location through the loading algorithm using the loaded information
the controller is configured to transfer an optimal cargo deployment sequence and disposal location derived as a simulator result to the client device; and
the client device is configured to transmit a logistics facility control instruction according to the cargo deployment sequence and the deployment location to the interface through the server.

14. The system of claim 1, wherein the interface is an Internet of Things interface (IoT I/F).

15. An automated logistics facility operation method of a client device operating based on a server, the method comprising:
selecting, by the client device, whether a CPS mode or a simulation mode is to be executed during a normal operation of the server;
receiving, by the client device, a digital twin service based on the facility data synchronized with an actual logistics facility in real time, by communicating with an interface and checking facility data, when the CPS mode is selected;
requesting, by the client device, an operation of a task parser for generating a work command, when the simulation mode is selected;
loading information of the server according to a work command generating processor of the task parser; and
calling, by the client device, a packaging simulator according to the loading of the loading information and receiving a loading sequence result value derived through a loading algorithm-based simulation.

16. The method of claim 15, wherein the receiving the loading sequence result value comprises:
generating a cargo list to be loaded for each destination according to a reality-based simulation condition through linking with an upper enterprise resource planning (ERP) system or a virtual simulation condition by a user;
loading a loaded cargo of a loading platform, a loaded cargo of a cargo container, and a stored cargo of an automated warehouse; and
generating 3D coordinates of the loaded cargo container and calculating filtered according to simulation scheduling through the packaging simulator cargo list target coordinates filtered according to simulation scheduling through the packaging simulator.

17. The method of claim 15, wherein the loading algorithm through the packaging simulator determines a batch cargo in a cargo container considering a value of a determination function of a lower unit of priority assignment, lower disposal, and avoidance rule,
wherein the determining the batch cargo comprises:
determining double loading prohibition, shipment properties, and a transit location;
priority assignment balancing, for disposing a regular cargo in a lower portion and an irregular cargo in an upper portion;
solid/heavy weight balancing, for preferentially disposing a solid and heavy weighted cargo at a lower portion and calculating whether the disposed cargo is broken down.

18. The method of claim 15, further comprising, after receiving the loading sequence result value, re-calculating the loading sequence result value, and instructing an automated warehouse release and loading work command in a virtual environment, so as to control a logistics work of the actual logistics facility mirrored based on the virtual environment according to the instruction through the server.

19. The method of claim 16, further comprising, after the controlling the logistics work:
monitoring an operation state the actual logistics facility through mirroring with the CPS mode and identifying whether the loading work is completed;
logging the identified loading work result (OK/NG) into a database of the server; and
outputting a loading sequence report in a simulation based on a cargo log and a time chart of an object logged in the DB or playing a black box image in the form of animation.

20. The method of claim 15, wherein the loading information comprises at least one piece of information among a cargo entering/releasing schedule of an aircraft or a ship, sequence, types, and sizes of available cargo containers, the cargo-entered state within information and an automated warehouse reservation cargo of the enterprise resource planning (ERP), a real-time loaded status of the cargo container.
